(19) United States
(12) Patent Application Publication
(10) Pub. No.: US 2012/0062298 A1
(43) Pub. Date: Mar. 15, 2012

(54) FLIP-FLOP ARCHITECTURE FOR MITIGATING HOLD CLOSURE

(75) Inventors: Sumanth Reddy PODDUTUR, Bangalore (IN); Prakash Narayanan, Bangalore (IN); Vivek Singhal, Bangalore (IN)

(73) Assignee: Texas Instruments Incorporated, Dallas, TX (US)

(21) Appl. No.: 12/882,240

(22) Filed: Sep. 15, 2010

(51) Int. Cl. H03K 3/00

(52) U.S. Cl. 327/218; 327/215

(57) ABSTRACT

A circuit for mitigating hold closure. The circuit includes a flip-flop having a clock input and an output. The circuit also includes a multiplexer. The multiplexer includes a select input coupled to the clock input of the flip-flop. The multiplexer also includes a first data input coupled to the output of the flip-flop. Further, the multiplexer includes an output coupled to a second data input of the multiplexer.

### TECHNICAL FIELD

Embodiments of the disclosure relate to the problem of hold closure in systems on a chip (SOCs).

### BACKGROUND

For flip-flops to function normally, it is required to maintain an input signal constant for a predefined time after a clock is triggered, referred as a hold time. If a cascade of flip-flops is used, a signal from a flip-flop should reach the succeeding flip-flop not before the completion of the hold time of the succeeding flip-flop. Since the data paths between the successive flip-flops are small, some delay must be introduced in the path to prevent hold time violations.

Hold time violations are prominent in scan flip-flop circuits. Scan flip-flops are ordinary flip-flops with the added option of a scan input pin. An enable pin is used to enable normal flop input (functional mode) or scan input (scan mode). Scan flip-flops are used to send test inputs and receive and observe test outputs. Delay buffers have been used to prevent hold-time violations, but conventional methods of introducing delay using buffers are inefficient with respect to size, consistency against process-temperature-voltage (PTV) reading, static timing analysis (STA) overheads and peak power consumption due to combinatorial logic toggling. Existing techniques for introducing delay, for example introducing buffers are also inefficient with respect to peak power and size.

### SUMMARY

An example of a circuit for mitigating hold closure includes a flip-flop having a clock input and an output. The circuit also includes a multiplexer. The multiplexer includes a select input coupled to the clock input of the flip-flop. The multiplexer also includes a first data input coupled to the output of the flip-flop. Further, the multiplexer includes an output coupled to a second data input of the multiplexer.

Another example of a circuit includes a flip-flop to receive a clock signal and to generate an output in response to the clock signal. The circuit also includes a multiplexer to provide an output determined by an output of the flip-flop and delayed by one-half of a clock cycle.

An example of a method of mitigating hold closure includes generating a flip-flop output signal in response to a first transition of a clock signal, coupling the flip-flop output signal to a first input of a multiplexer; and transmitting the flip-flop output signal through the multiplexer to an output of the multiplexer in response to a second transition of the clock signal.

### BRIEF DESCRIPTION OF THE VIEWS OF DRAWINGS

In the accompanying figures, similar reference numerals may refer to identical or functionally similar elements. These reference numerals are used in the detailed description to illustrate various embodiments and to explain various aspects and advantages of the disclosure.

FIG. 1 illustrates an environment of a flip-flop architecture for mitigating hold closure, according to which various embodiments can be implemented;

FIG. 2 is a block diagram of the flip-flop architecture for mitigating hold closure, in accordance with one embodiment;

FIG. 3 is a block diagram of the flip-flop architecture for mitigating hold closure, in accordance with another embodiment;

FIG. 4 is an exemplary timing diagram of a flop architecture for mitigating hold closure, in accordance with one embodiment; and

FIG. 5 is a flow chart illustrating a method for mitigating hold closure, in accordance with one embodiment.

### DETAILED DESCRIPTION OF THE EMBODIMENTS

Various embodiments discussed in this disclosure pertain to mitigating hold closure in a flip-flop architecture.

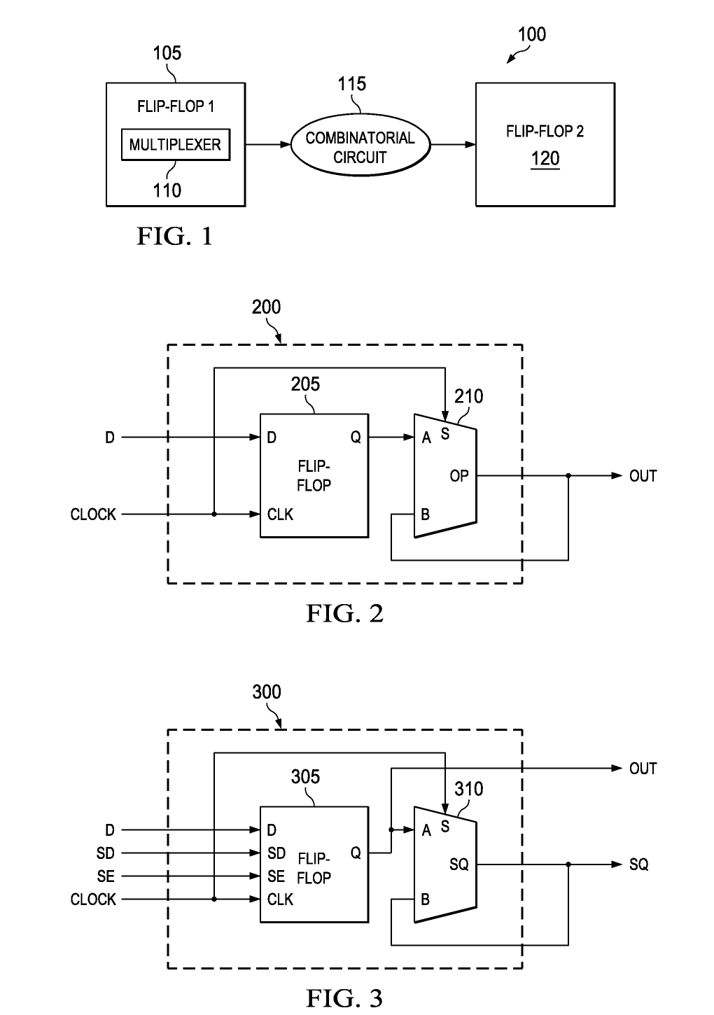

An environment 100 of a flip-flop architecture for mitigating hold closure is shown in FIG. 1. The environment 100 includes a flip-flop 105 coupled to a multiplexer 110. The flip-flop 105 including the multiplexer 110 is coupled to another flip-flop 120 through a combinational circuit 115. Examples of flip-flop include, but are not limited to, a delay (D) flip-flop, a toggle (T) flip-flop, a reset-set (RS) flip-flop and a JK flip-flop. The combinational circuit 115 is a type of digital logic, implemented using a Boolean logic, where the output is dependent on present inputs only. The combinational circuit 115 is used to perform Boolean algebraic functions on input signals or stored data. Examples of the combinational circuit 115 include a half adder, full adder, half subtractor, full subtractor, multiplexer, demultiplexer, encoder and decoder.

Various embodiments for enhancing flop flop architecture including the multiplexer are explained in conjunction with FIG. 2 and FIG. 3.

FIG. 2 is a block diagram of a flip-flop architecture 200 for mitigating hold closure in accordance with one embodiment. The architecture 200 includes a D flip-flop 205 coupled to a 2:1 multiplexer 210. The flip-flop 205 has a D input that receives a data signal and a clock input that is coupled to a clock signal. The clock input is referred to as “CLK”. The multiplexer 210 has three input ports referred as port ‘A’, port ‘B’ and port ‘S’ respectively. The port ‘A’ of the multiplexer 210 receives the output signal from an output port ‘Q’ of the flip-flop 205. The port ‘B’ of the multiplexer 210 receives the output signal of the multiplexer 210 from an output port labeled “OP” through a feedback path. The multiplexer 210 has an additional select input port referred to as ‘S’ that receives the clock signal. The output port labeled ‘OP’ outputs the output signal from the flip-flop 205 delayed by a half clock cycle.

During a rising edge of the clock signal, an input signal at port ‘D’ of the flip-flop 205 is relayed to port ‘Q’ of the flip-flop 205. The input signal is further fed to the port ‘A’ of the multiplexer 210. Further, logic high value of the clock, the multiplexer 210 outputs the signal at the port ‘B’. As port ‘B’ is coupled to the output port ‘OP’ of the multiplexer 210 via feedback path, the output ‘OUT’ during the rising edge of clock is the previously stored output. Thus the output signal at the Q port of the flip-flop 205 is not transmitted by the multiplexer 210 during the logic high value of the clock.

During a logic low value of the clock, the signal held at port ‘A’ of the multiplexer 210 is transmitted to its output port ‘OP’. The signal held at port ‘A’ of the multiplexer 210 is the output that was assumed by the flip-flop 205 during the rising edge of clock signal. Thus the output of flip-flop 205 is obtained as the output of the multiplexer 210 during the logic low of the clock signal. Thus the multiplexer 210 delays the output of flip-flop 205 by exactly one half cycle of clock. This delay of exactly one half cycle ensures mitigation of a hold violation.

In some embodiments, the output of the multiplexer is coupled to a first combinatorial circuit of a plurality of combinatorial circuits of an integrated circuit. Using the flip-flop 200, the first combinatorial circuit toggles according to the output of the multiplexer, that distributes consumption of power by the integrated circuit across a first type of edge of the clock signal and a second type of edge of the clock signal.

FIG. 3 illustrates a block diagram of the flip-flop architecture 300 for mitigating hold closure in accordance with another embodiment. The architecture includes a scan D flip-flop 305 coupled to a 2:1 multiplexer 310. The flip-flop 305 has four input ports and two output ports. The flip-flop 305 has an input port referred to as ‘D’ to receive functional mode input, an input port referred to as ‘SD’ to receive scan input during scan mode, an input port referred to as ‘CLK’ to receive a clock signal, and a scan enable port referred to as ‘SE’ to receive a scan enable signal. The scan enable signal is used for selecting the functional mode or the scan mode of the flip-flop 305. The flip-flop 305 has an output port referred to as ‘Q’ to provide a functional mode output signal. The flip-flop architecture 300 can thus be used to implement a functional mode of operation. The functional mode of operation was explained previously in conjunction with FIG. 2. The multiplexer 310 has three input ports referred to as port ‘A’, port ‘B’ and port ‘S’ respectively. The port ‘A’ receives the output signal from the output port ‘Q’ of the flip-flop 305. The port ‘B’ receives the output signal of the multiplexer 310 from an output port labeled “SQ” through a feedback path. The multiplexer 310 has a select input port referred to as ‘S’ that receives the clock signal. The output signal from the flip-flop 305 is provided at the multiplexer output port SQ after a half clock cycle delay.

In some embodiments, where functional timing for the flip-flop needs to be maintained, the scan flip-flop 300 as illustrated in FIG. 3 can be used. Here, for the flip-flop 300 to operate in a functional mode, the output signal from the output port ‘Q’ is fed to an output port ‘OUT’. Further, during the scan mode, the multiplexer 310 is coupled to the output port ‘Q’. A delayed output signal is then provided at the output port ‘SQ’ during the scan mode of the flip-flop 300.

During the rising edge of a clock signal, in scan mode, the signal at port ‘SD’ of the flip-flop 305 is relayed to port ‘Q’ of the flip-flop 305. The signal is further fed to input port ‘A’ of the multiplexer 310. Further, during logic high of the clock, the multiplexer 310 outputs the signal at the input port B. As port ‘B’ is coupled to the output port ‘SQ’ of the multiplexer 310 through the feedback path, the output ‘SQ’ during the logic high of the clock is the previously stored output. Thus the output signal at the flip-flop 305 is delayed by the multiplexer 310 during the rising edge of the clock.

During the logic low of the clock, in scan mode, the signal at port ‘A’ of the multiplexer 310 is relayed to the output port ‘SQ’ of the multiplexer. The signal held at port ‘A’ of the multiplexer 310 is the output of the flip-flop 305 during the rising edge of the clock signal. The output of the flip-flop 305 during the rising edge of the clock signal is obtained at the output of multiplexer 310 during the logic low of the clock signal. Thus the multiplexer 310 delays the output of flip-flop 305 by exactly one half cycle of clock. This delay of exactly one half cycle ensures mitigation of a hold violation.

In an embodiment, the scan enable signal ‘SE’ is asserted to initiate scan mode. Plurality of flip-flops (300) in cascaded mode is used to test internal nodes in integrated circuit. Each flip-flop in the integrated circuits is connected into a long shift register, one input pin provides the data to a cascaded chain, and one output pin is connected to the output of the cascaded chain. An arbitrary pattern is entered into chain of flips flops, and the state of every flip flop can be read out using the integrated circuit's clock signal. Using the flip-flop 300 of the present disclosure, the hold time violations for the plurality of flip-flops in the scan mode is overcome by introducing half clock cycle delay.

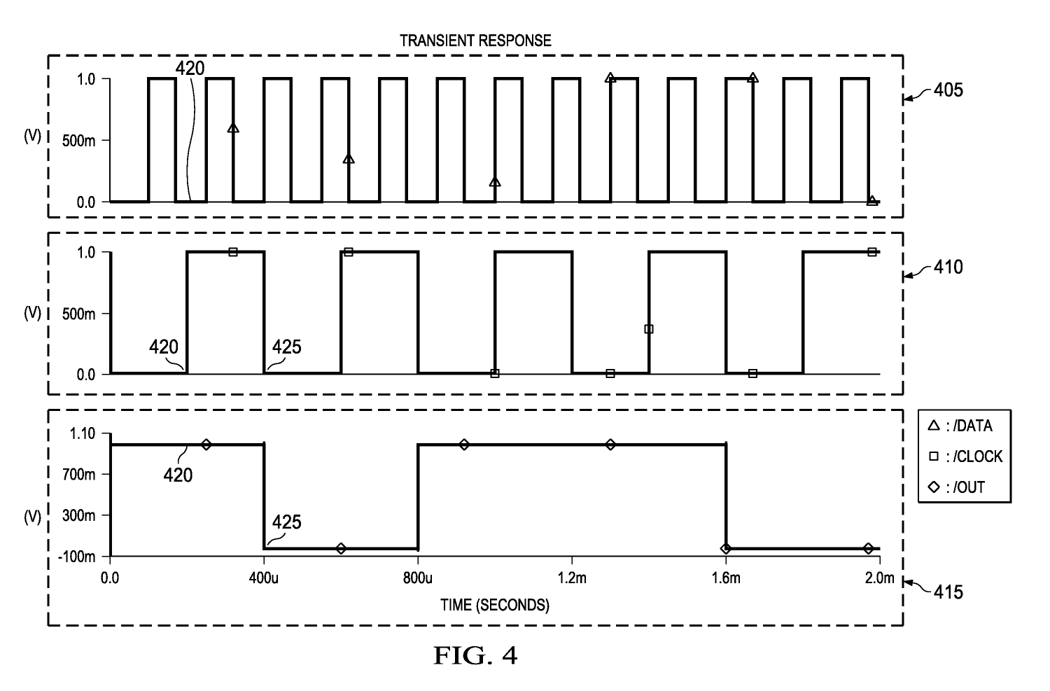

The transference of signals through the multiplexer 310 can be better explained in conjunction with FIG. 4.

FIG. 4 is an exemplary timing diagram of a flip-flop architecture in accordance with one embodiment. The block 405 depicts a waveform for data at the input of the flip-flop. The Y-axis represents voltage in volts and the X-axis represents time in seconds in block 405. The block 410 represents the clock signal used in the flop architecture. The Y-axis represents voltage in volts and the X-axis represents time in seconds in block 410. The block 415 represents the output of the multiplexer. The Y-axis represents voltage in volts and the X-axis represents time in seconds in the block 415.

In block 405, at time 420, the data at the input of the flip-flop is at a logic low. Time 420 correspond to a rising edge of the clock signal in block 410. The output of the multiplexer at 420 is held to its previous value, logic high, as shown in block 415. At time 425 in block 410, corresponding to the falling edge of the clock signal in block 415, the output of the multiplexer goes to the logic low value. Thus the input to the flip-flop at the rising edge of the clock signal is obtained at the output of multiplexer at the falling edge of the clock signal. Thus a delay of one half cycle of clock is realized.

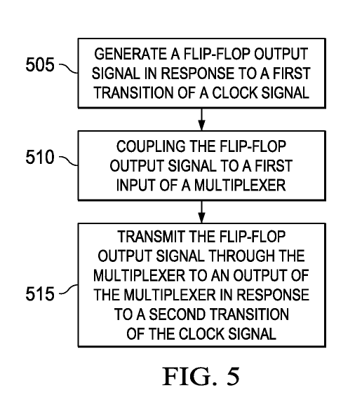

Referring to FIG. 5, various steps involved in introducing a half clock cycle delay are illustrated.

An input signal is fed to a flip-flop.

At step 505, a flip-flop output signal is generated in response to a first transition of a clock signal. The first transition corresponds to a rising edge of the clock signal.

On the rising edge of the clock signal, the input signal is latched by the flip-flop and transmitted to the flip flop output. The flip-flop output signal corresponds to the input signal.

In some embodiments, the input signal is held by the flip-flop for a predefined time prior to receiving of the clock signal by the flip-flop.

At step 510, the flip-flop output signal is coupled to a first input of a multiplexer.

At step 515, the flip-flop output signal is transmitted through the multiplexer to an output of the multiplexer in response to a second transition of the clock signal. The second transition corresponds to logic low of the clock signal.

For a logic high clock signal, the multiplexer transmits data at a second input of the multiplexer to the output of the multiplexer. The data at the second input is a signal output by the multiplexer during a previous transition of the clock signal.

In the foregoing discussion, each of the terms “coupled” and “connected” refers to either a direct electrical connection or mechanical connection between the devices connected or an indirect connection through intermediary devices.

The foregoing description sets forth numerous specific details to convey a thorough understanding of embodiments of the disclosure. However, it will be apparent to one skilled in the art that embodiments of the disclosure may be practiced without these specific details. Some well-known features are not described in detail in order to avoid obscuring the disclosure. Other variations and embodiments are possible in light of above teachings, and it is thus intended that the scope of disclosure not be limited by this Detailed Description, but only by the Claims.

What is claimed is:

1. A circuit for mitigating hold closure comprising:
a flip-flop having a clock input and an output; and
a multiplexer having
a select input coupled to the clock input of the flip-flop,
a first data input coupled to the output of the flip-flop, and
an output coupled to a second data input of the multiplexer.

2. The circuit as claimed in claim 1, wherein the flip-flop is a D-type flip-flop.

3. The circuit as claimed in claim 1, wherein the flip-flop is a scan flip-flop.

4. The circuit as claimed in claim 1, wherein the flip-flop and the multiplexer are comprised in an integrated circuit.

5. The circuit as claimed in claim 1 wherein the multiplexer provides an output determined by an output of the flip-flop and delayed by one-half of a clock cycle.

6. The circuit as claimed in claim 5, wherein the multiplexer provides the output according to a logic low of a clock signal.

7. The circuit as claimed in claim 4 wherein the output of the multiplexer is coupled to a first combinatorial circuit of a plurality of combinatorial circuits of the integrated circuit.

8. The circuit as claimed in claim 7, wherein the first combinatorial circuit toggles according to the output of the multiplexer, thereby distributing consumption of power by the integrated circuit across a first type of edge of the clock signal and a second type of edge of the clock signal.

9. The circuit as claimed in claim 1, wherein the circuit is operated across one or more values of process, temperature and voltage.

10. A circuit comprising:
a flip-flop to receive a clock signal and to generate an output in response to the clock signal; and
a multiplexer to provide an output determined by an output of the flip-flop and delayed by one-half of a clock cycle.

11. The circuit as claimed in claim 1, wherein the circuit is operated across one or more values of process, temperature and voltage.

12. A method of timing a flip-flop comprising:
generating a flip-flop output signal in response to a first transition of a clock signal;
coupling the flip-flop output signal to a first input of a multiplexer; and
transmitting the flip-flop output signal through the multiplexer to an output of the multiplexer in response to a second transition of the clock signal.

13. The method as claimed in claim 12, wherein the flip-flop output signal is transmitted to the output of the multiplexer for a logic low of the clock signal.

14. The method as claimed in claim 12, wherein data at a second input of the multiplexer is transmitted to the output of the multiplexer for a logic high of the clock signal.

15. The method as claimed in claim 14, wherein the data at the second input is a signal output by the multiplexer during a previous transition of the clock signal.

16. The method as claimed in claim 12, wherein an input signal to the flip-flop is held for a predefined time prior to the receiving of the clock signal.
